(19) United States
(12) Patent Application Publication
(10) Pub. No.: US 2025/0126800 A1
(43) Pub. Date: Apr. 17, 2025

(54) SEMICONDUCTOR MEMORY UNDERLYING CIRCUIT AND PREPARATION METHOD FOR THE SAME

(71) Applicant: CHENGDU PBM TECHNOLOGY LTD., Chengdu, Sichuan (CN)

(72) Inventors: Jack Zezhong PENG, Chengdu, Sichuan (CN); Ke WANG, Chengdu, Sichuan (CN)

(73) Assignee: CHENGDU PBM TECHNOLOGY LTD., Chengdu, Sichuan (CN)

(21) Appl. No.: 18/695,219

(22) PCT Filed: Feb. 21, 2023
(86) PCT No.: PCT/CN2023/077346

§ 371 Date: Mar. 25, 2024

(30) Foreign Application Priority Data
Dec. 20, 2022 (CN) 202211641410.5

(51) Int. Cl. H10B 43/40; H10B 41/10; H10B 41/20; H10B 41/40; H10B 43/10; H10B 43/20

(52) U.S. Cl. CPC H10B 43/40; H10B 41/10; H10B 41/20; H10B 41/40; H10B 43/10; H10B 43/20

(57) ABSTRACT

Provided are a semiconductor memory underlying circuit and a preparation method for the same. The semiconductor memory underlying circuit of the present disclosure includes a row line layer, a column line layer located above the row line layer, and an insulating isolation layer between the row line layer and the column line layer. A predetermined number of row lines made of a doped semiconductor material are provided inside the row line layer, and a predetermined number of column lines made of a conductive material are provided inside the column line layer, with directions of the row lines and the column lines being perpendicular to each other. Metal oxide semiconductor (MOS) holes penetrating the column line layer and the insulating isolation layer are provided at intersections of the row lines and column lines. An upper segment and a lower segment of the MOS hole both are filled with conductive materials.

This application is a National Stage application under 35 U.S.C. 371 of International Patent Application No. PCT/CN2023/077346, filed Feb. 21, 2023, which claims the benefit and priority of Chinese Patent Application No. 202211641410.5, filed Dec. 20, 2022; the disclosures of all of which are incorporated herein by reference in their entireties.

### TECHNICAL FIELD

The present disclosure relates to integrated circuit technologies, and in particular, to a semiconductor memory technology.

### BACKGROUND

Currently, 3D memories (such as NAND, resistance random access memory, and phase-change memory) typically use planar-process fabricated metal oxide semiconductor (MOS) transistors as select transistors for vertical bit lines of 3D memories. Since the critical dimensions and occupied area of planar MOS select transistors need to be compatible with densely packed 3D memory arrays, the use of planar MOS select transistors is limited by planar processes. This limitation can cause the subsequently stacked 3D memories to occupy a large chip area. Therefore, the drawback of this approach is that it occupies a large chip area, making it incompatible with the densely packed 3D memory array. Another type of select transistor for vertical bit lines is a vertical MOS select transistor, where the vertically oriented MOS channel is in line with the 3D vertical bit lines. The conduction status of the vertical MOS transistor is controlled by horizontal source select lines and horizontal gate select lines, which are oriented orthogonally and interleaved, which thereby selects the bit line connected to the drain of the vertical MOS transistor. Although the vertical MOS select transistor directly below the 3D memory array is compatible with the densely packed 3D memory array, it requires the select transistor to be placed within an active area of the underlying substrate, as a result of which, other essential peripheral circuits (such as input/output (I/O) circuits and control circuits) can only be placed outside the 3D memory array, occupying a significant portion of the chip area. A vertical MOS select transistor positioned on top of the substrate rather than under the substrate (U.S. Pat. No. 9,065,044 B2) avoids the aforementioned issues but requires a complex and difficult-to-control high-temperature annealing process for out-diffusion the re-doped source into lightly doped MOS channels of different conductivity types, leading to higher manufacturing costs.

### SUMMARY

The technical problem to be solved by the present disclosure is to provide a semiconductor memory underlying circuit that occupies a smaller chip area and a preparation method for the same.

The technical solution adopted to address the technical problem in the present disclosure is a semiconductor memory underlying circuit, including a row line layer, a column line layer located above the row line layer, and an insulating isolation layer between the row line layer and the column line layer. A bit line contact layer is located above the column line layer. A predetermined number of row lines made of a heavily-doped low-resistance semiconductor material are provided inside the row line layer, and a predetermined number of column lines made of a conductive material are provided inside the column line layer, with directions of the row lines and the column lines being perpendicular to each other. MOS holes penetrating the bit line contact layer, the column line layer, and the insulating isolation layer are provided at intersections of the row lines and column lines. In the bit line contact layer, positions corresponding to the MOS holes are filled with a semiconductor material, and a doping type of the semiconductor material is the same as that of the row lines.

Inside the MOS hole, positions corresponding to the column line layer and the insulating isolation layer are filled with a semiconductor material. The semiconductor material has a doping type opposite to that of the row line and is in contact with the row line. The semiconductor materials in upper and lower segments of the MOS hole are in direct contact with each other.

The semiconductor material in the MOS hole is isolated from an inner wall of the MOS hole by a gate insulating layer.

Furthermore, the MOS hole is rectangular, elliptical, circular, or the like.

The column lines are made of a low-resistance material such as a doped semiconductor material, metal, or metal silicide.

The present disclosure further provides a preparation method for a semiconductor memory underlying circuit, including the following steps:

(1) setting a row line layer on a bottom basic circuit layer, where the row line layer has a predetermined number of parallel row lines made of a heavily-doped low-resistance semiconductor material;

(2) covering the row line layer with an insulating isolation layer, and then setting a column line layer on the insulating isolation layer, where the column line layer has a predetermined number of parallel column lines perpendicular to the row lines, and the column lines are made of a conductive material;

(3) covering the column line layer with an insulating dielectric material as a bit line contact layer;

(4) forming holes at intersections of the row lines and the column lines, where the holes penetrate the bit line contact layer, the column line layer, and the insulating isolation layer, the bottom of the hole exposes the row line, and an opening of the hole is located on an upper surface of the bit line contact layer;

(5) coating an inner wall of the hole with a gate insulating dielectric material, and then removing the gate insulating dielectric material at the bottom of the hole, to expose the row line at the bottom of the hole; and

(6) filling positions corresponding to the column line layer and the insulating isolation layer in the hole with a semiconductor material of a doping type opposite to that of the row line, and then filling the rest of the hole with a semiconductor material of a doping type the same as that of the row line; alternatively, filling the entire hole with a semiconductor material of a doping type opposite to that of the row line and then injecting impurities at a position corresponding to the bit line contact layer to form a semiconductor material with a conductivity type the same as that of the row line.

The method further includes the following steps:

connecting each row line and each column line to the bottom basic circuit layer; and connecting upper ends of the MOS holes in the bit line contact layer to vertical bit lines of an upper 3D memory device.

The present disclosure has the following beneficial effect: the present disclosure can control and select a set of vertical bit lines shared by memory cells from multiple separate stacked layers of a 3D memory array. The present disclosure does not occupy the underlying region, which is available for other memory circuits, thereby reducing the size of the 3D memory chip. The preparation process of the present disclosure is simple and cost-effective.

### BRIEF DESCRIPTION OF THE DRAWINGS

FIG. 1 illustrates the principle of U.S. Pat. No. 9,065,044B2;

FIG. 2 is a schematic diagram of step (1) in Embodiment 1;

FIG. 3 is a cross-sectional view taken along A-A′ in FIG. 2;

FIG. 4 is a schematic diagram of step (2) in Embodiment 1;

FIG. 5 is a cross-sectional view taken along A-A′ in FIG. 4;

FIG. 6 is a schematic diagram of step (3) in Embodiment 1;

FIG. 7 is a schematic diagram of step (4) in Embodiment 1;

FIG. 8 is a cross-sectional view taken along A-A′ in FIG. 7;

FIG. 9 is a schematic diagram of step (5) in Embodiment 1;

FIG. 10 is a cross-sectional view taken along A-A′ in FIG. 9;

FIG. 11 is a schematic diagram of filling entire holes with a channel region material;

FIG. 12 is a schematic diagram of etching away the channel region material in an upper segment of the hole and filling the upper segment with a row line material;

FIG. 13 is a schematic diagram showing positions of an underlying circuit and a memory area part; and

FIG. 14 is a schematic diagram of Embodiment 2.

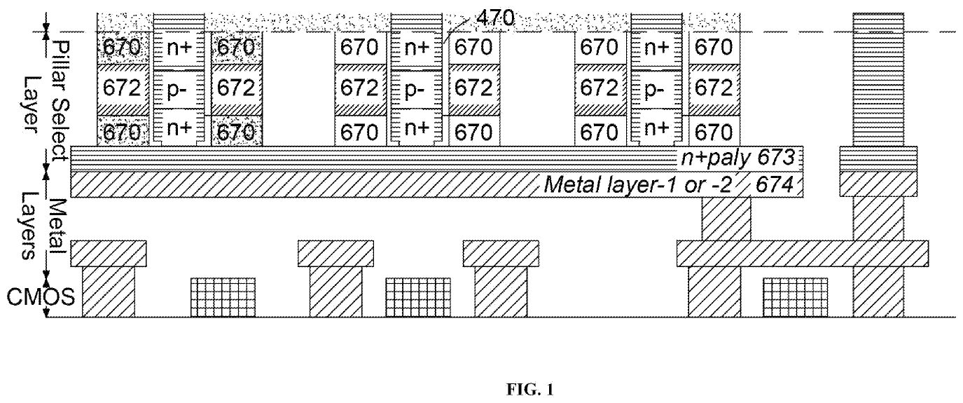

### DETAILED DESCRIPTION OF THE EMBODIMENTS

### Embodiment 1: Preparation Method

This embodiment includes the following steps:

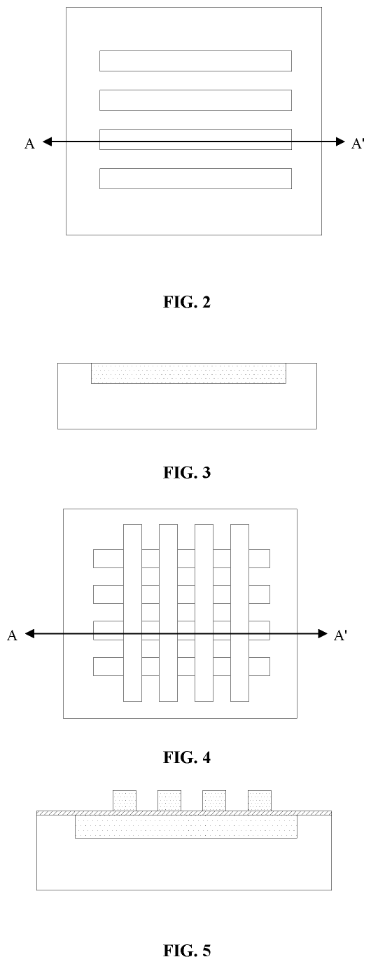

(1) Set a row line layer on a bottom basic circuit layer, where the row line layer has a predetermined number of parallel row lines made of a doped low-resistance semiconductor material. Referring to FIG. 2 and FIG. 3, mask-controlled etching is performed to form a plurality of parallel straight-line grooves. The doped semiconductor material is deposited in the straight-line grooves to form the row lines. FIG. 3 is a cross-sectional view taken along A-A′ in FIG. 2.

(2) Deposit an interlayer insulating isolation layer on top of the row line layer, and then set a column line layer on top of the interlayer insulating isolation layer, where the column line layer has a predetermined number of parallel column lines perpendicular to the row lines, and the column lines are made of a conductive material. Referring to FIG. 4 and FIG. 5, the conductive material (such as heavily-doped polycrystalline silicon) is deposited on the interlayer insulating isolation layer, defined by a mask, and etched to form the column lines. FIG. 4 is a top view. In order to show the relationship between the row lines and the column lines, the row lines are shown under the column lines, and the insulating isolation layer between them is ignored (or the insulating isolation layer is treated as transparent).

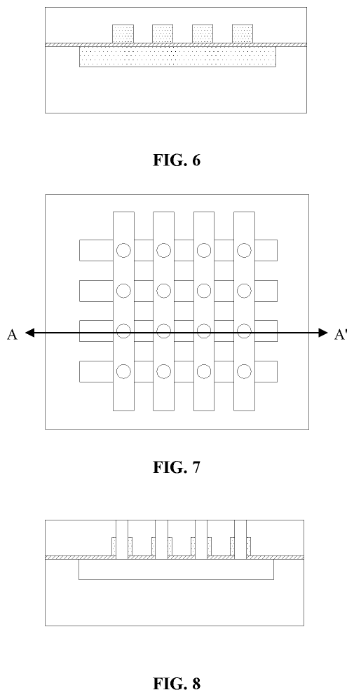

(3) Deposit an insulating material on the interlayer insulating isolation layer on which the column lines are arranged, where the insulating material in the plane of the column lines, together with the column lines, forms the column line layer, and the insulating material above the column lines is located in a bit line contact layer, as shown in FIG. 6.

(4) Form holes at intersections of the row lines and the column lines, where the holes penetrate the bit line contact layer, whereas the column line layer, and the interlayer insulating isolation layer, the bottom of the hole exposes the row line, and an opening of the hole is located on an upper surface of the bit line contact layer. At the position of the hole, a major part of a MOS transistor structure will be formed in subsequent steps. Therefore, the hole is referred to as a MOS hole. Referring to FIG. 7 and FIG. 8, similarly, in order to show the positions of the holes at the intersections of the row lines and the column lines, the interlayer insulating isolation layer is ignored in FIG. 7.

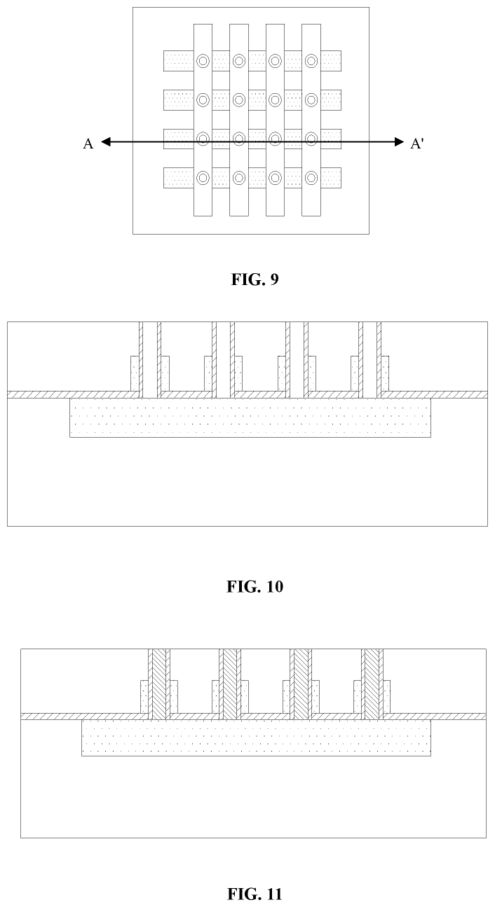

(5) Coat an inner wall of the hole with a gate insulating dielectric material, and then remove the gate insulating dielectric material at the bottom of the hole, to expose the row line at the bottom of the hole, as shown in FIG. 9 and FIG. 10.

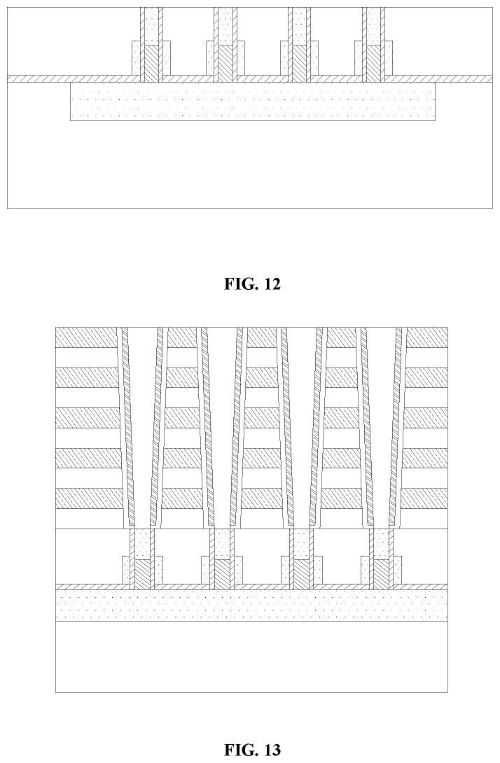

(6) In a lower segment of the hole, fill positions corresponding to the column line layer and the interlayer insulating isolation layer with a semiconductor material of a doping type opposite to that of the row line, to form a channel region, and then in the rest of the hole, fill a position corresponding to the bit line contact layer with a semiconductor material of a doping type the same as that of the row line, as shown in FIG. 11 and FIG. 12. FIG. 11 illustrates the step of filling the entire hole with a channel region material, and FIG. 12 illustrates the step of etching away the channel region material in the upper segment of the hole and filling the upper segment with a row line material.

At this point, the MOS transistor structure is formed, with the column lines serving as the gate of the MOS transistor, the insulating dielectric material on the inner walls of the holes acting as the gate dielectric, and the doped semiconductor materials at the upper and lower ends of the channel region forming the source and the drain. Alternatively, the entire hole is filled with a semiconductor material of a doping type opposite to that of the row line and then impurities are injected at a position corresponding to the bit line contact layer to form a semiconductor material with a conductivity type the same as that of the row line.

Finally, the memory area part is prepared on the underlying circuit, as shown in FIG. 13. The structure of the memory area part belongs to the prior art, as described in Chinese Patent Application No. 2021102335743, “Preparation Method for High-Density Three-Dimensional Programmable Memory.”

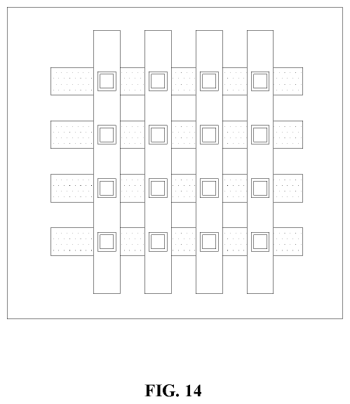

The MOS holes in Embodiment 1 are circular, as shown in FIG. 9. As an improvement, to enhance MOS channel control performance, the MOS holes can be rectangular, as shown in FIG. 14.

### Embodiment 2

Referring to FIG. 14 and FIG. 9, this embodiment provides a semiconductor memory underlying circuit, including a row line layer, a column line layer located above the row line layer, and an interlayer insulating isolation layer between the row line layer and the column line layer. A predetermined number of row lines made of a doped semiconductor material are provided inside the row line layer, and a predetermined number of column lines made of a conductive material are provided inside the column line layer, with directions of the row lines and the column lines being perpendicular to each other. MOS holes penetrating the column line layer and the interlayer insulating isolation layer are provided at intersections of the row lines and column lines.

An upper segment and a lower segment of the MOS hole both are filled with conductive materials. The semiconductor material in the upper segment of the MOS hole has a doping type the same as that of the row line. The semiconductor material in the lower segment of the MOS hole has a doping type opposite to that of the row line and is in contact with the row line. The semiconductor materials in the upper and lower segments are in direct contact with each other.

The semiconductor material filled in the MOS hole is isolated from an inner wall of the MOS hole by an insulating layer.

Furthermore, the MOS hole is rectangular.

The column lines are made of a doped low-resistance material or metal silicide.

What is claimed is:

1. A semiconductor memory underlying circuit, comprising a row line layer, a column line layer located above the row line layer, and an insulating isolation layer between the row line layer and the column line layer, wherein a predetermined number of row lines made of a doped semiconductor material are provided inside the row line layer, and a predetermined number of column lines made of a conductive material are provided inside the column line layer, with directions of the row lines and the column lines being perpendicular to each other; metal oxide semiconductor (MOS) holes penetrating the column line layer and the insulating isolation layer are provided at intersections of the row lines and column lines;
an upper segment and a lower segment of the MOS hole both are filled with conductive materials; the semiconductor material in the upper segment of the MOS hole has a doping type the same as that of the row line; the semiconductor material in the lower segment of the MOS hole has a doping type opposite to that of the row line and is in contact with the row line; the semiconductor materials in the upper and lower segments are in direct contact with each other; and
the semiconductor material filled in the MOS hole is isolated from an inner wall of the MOS hole by an insulating layer.

2. The semiconductor memory underlying circuit according to claim 1, wherein the MOS holes are rectangular.

3. The semiconductor memory underlying circuit according to claim 1, wherein the column lines are made of a doped semiconductor material.

4. A preparation method for a semiconductor memory underlying circuit, comprising the following steps:
(1) setting a row line layer on a bottom basic circuit layer, wherein the row line layer has a predetermined number of parallel row lines made of a doped semiconductor material;
(2) covering the row line layer with an insulating isolation layer, and then setting a column line layer on the insulating isolation layer, wherein the column line layer has a predetermined number of parallel column lines perpendicular to the row lines, and the column lines are made of a conductive material;
(3) forming holes at intersections of the row lines and the column lines, wherein the holes penetrate the column line layer and the insulating isolation layer, a bottom of the hole exposes the row line, and an opening of the hole is located on an upper surface of the column line layer;
(4) coating an inner wall of the hole with an insulating dielectric material, and then removing the insulating dielectric material at the bottom of the hole, to expose the row line at the bottom of the hole; and
(5) filling a lower segment of the hole with a semiconductor material of a doping type opposite to that of the row line, and then filling the rest of the hole with a semiconductor material of a doping type the same as that of the row line.

5. The preparation method for a semiconductor memory underlying circuit according to claim 4, further comprising the following steps:
connecting each row line and each column line to the bottom basic circuit layer.
